(19) United States
(12) Patent Application Publication
(10) Pub. No.: US 2026/0060087 A1
(43) Pub. Date: Feb. 26, 2026

(54) SEMICONDUCTOR DEVICE

(71) Applicants: KABUSHIKI KAISHA TOSHIBA, Kawasaki-shi (JP); TOSHIBA ELECTRONIC DEVICES & STORAGE CORPORATION, Kawasaki-shi (JP)

(72) Inventor: Masaaki YOSHIKAWA, Yokohama Kanagawa (JP)

(73) Assignees: KABUSHIKI KAISHA TOSHIBA, Kawasaki-shi (JP); TOSHIBA ELECTRONIC DEVICES & STORAGE CORPORATION, Kawasaki-shi (JP)

(21) Appl. No.: 19/374,110

(22) Filed: Oct. 30, 2025

Related U.S. Application Data
(63) Continuation of application No. PCT/JP2024/013399, filed on Apr. 1, 2024.

(30) Foreign Application Priority Data
Aug. 7, 2023 (JP) 2023-128907

(51) Int. Cl. H01L 23/427; H01L 23/00; H01L 23/40; H01L 25/065

(52) U.S. Cl. CPC H01L 23/427; H01L 23/40; H01L 24/48; H01L 25/0655; H01L 24/32; H01L 24/73; H01L 2224/32225; H01L 2224/48227; H01L 2224/73265

(57) ABSTRACT

A semiconductor device of an embodiment includes a main body which has a substrate and a chip mounted on a device surface facing one side in a first direction among outer surfaces of the substrate. The semiconductor device includes a housing which accommodates the main body. The semiconductor device includes a heat transfer pin. The housing has a lid member that faces the device surface. The heat transfer pin is held by the lid member and extends from the lid member toward the chip.

### CROSS-REFERENCE TO RELATED APPLICATION

This application is based upon and claims the benefit of priority from Japanese Patent Application No. 2023-128907, filed on Aug. 7, 2023, the entire contents of which are incorporated herein by reference.

### FIELD

Embodiments described herein relate generally to a semiconductor device.

### BACKGROUND

In semiconductor devices, the amount of heat generated in chips mounted on a substrate tends to increase. Further, when electrodes to be connected to wires are provided on the surface of the chip, and when the chip is covered with a resin material to ensure the insulating properties of the chip, it is difficult to dissipate heat of the chip from the surface of the chip, so there is a risk that the temperature of the chip will become excessively high. If the temperature of the chip becomes excessively high, there is a risk that the operation of the semiconductor device will become unstable.

### BRIEF DESCRIPTION OF THE DRAWINGS

FIG. 1 is a schematic cross-sectional view showing a semiconductor device of a first embodiment.

FIG. 2 is a partially enlarged schematic cross-sectional view showing a part of the semiconductor device of the first embodiment.

FIG. 3 is a schematic view of a chip of the first embodiment as viewed from above.

FIG. 4 is a schematic cross-sectional view showing a semiconductor device of a second embodiment.

FIG. 5 is a schematic cross-sectional view showing a semiconductor device of a third embodiment.

FIG. 6 is a schematic cross-sectional view showing a semiconductor device of a fourth embodiment.

### DETAILED DESCRIPTION

A semiconductor device of an embodiment includes a main body which has a substrate and a chip mounted on a device surface facing one side in a first direction among in outer surfaces of the substrate. The semiconductor device includes a housing which accommodates the main body. The semiconductor device includes a heat transfer pin. The housing has a lid member that faces the device surface. The heat transfer pin is held by the lid member and extends from the lid member toward the chip.

Hereinafter, a semiconductor device of the embodiment will be described with reference to the drawings.

A first direction D1 shown in each drawing is the direction in which the device surface on which the chip is mounted faces among the outer surfaces of the substrate. In the following description, the side toward which the arrow of the first direction D1 points (+D1 side) is referred to as “one side of the first direction D1” or “upper side,” and the side opposite to the side toward which the arrow of the first direction D1 points (−D1 side) is referred to as “the other side of the first direction D1” or “lower side.” Furthermore, the terms of the “upper side” and “lower side” do not indicate a relationship to the direction of gravity. In the following description, the upward facing surface of among the outer surfaces of each member and layer constituting the semiconductor device will be referred to as the front surface, and the downward facing surface will be referred to as the back surface.

A second direction D2 shown in each drawing is the direction orthogonal to the first direction D1. A third direction D3 shown in each drawing is the direction orthogonal to both the first direction D1 and the second direction D2.

### First Embodiment

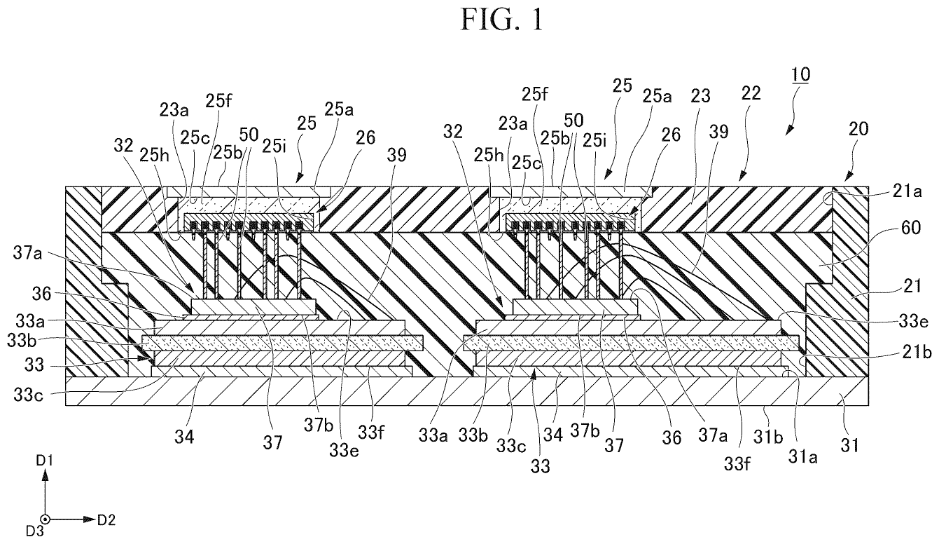

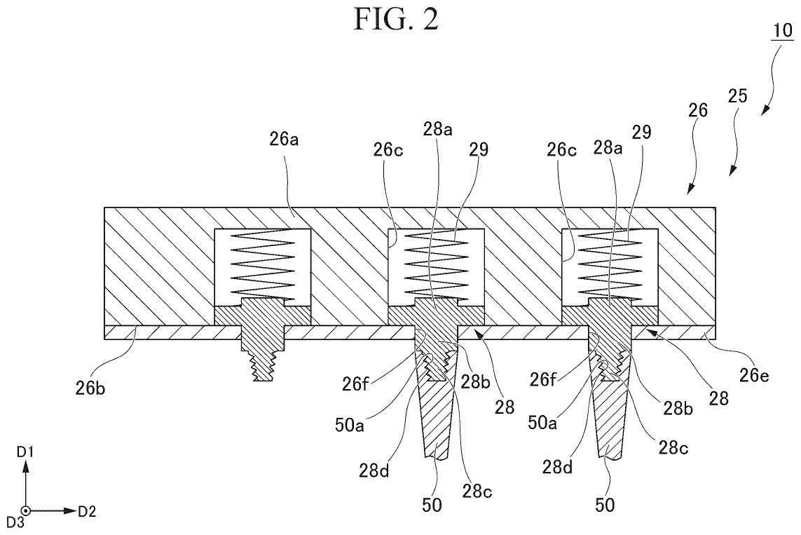

FIG. 1 is a schematic cross-sectional view of a semiconductor device 10 of this embodiment. The semiconductor device 10 of this embodiment is, for example, a semiconductor device such as a metal oxide semiconductor field effect transistor (MOSFET) and an insulated gate bipolar transistor (IGBT). The semiconductor device 10 includes a housing 20, a heat dissipation plate 31, a main body 32, and a heat transfer pin 50. As shown in FIG. 2, the semiconductor device 10 includes an elastic member 29.

As shown in FIG. 1, the housing 20 accommodates the main body 32 and the heat transfer pin 50 therein. The housing 20 has a peripheral wall portion 21 and a lid member 22.

The peripheral wall portion 21 surrounds the main body 32 and the heat transfer pin 50. The peripheral wall portion 21 has a cylindrical shape that extends in the first direction D1. In this embodiment, the peripheral wall portion 21 has a rectangular cylindrical shape. The peripheral wall portion 21 may have other shapes, such as a cylindrical shape or a hexagonal cylindrical shape. The peripheral wall portion 21 has a first opening 21a that opens to the upper side and a second opening 21b that opens to the lower side. In this embodiment, the peripheral wall portion 21 is formed of resin. The peripheral wall portion 21 may be formed of metal.

The lid member 22 has a plate shape that spreads in a direction orthogonal to the first direction D1. In this embodiment, the lid member 22 has a substantially rectangular shape as viewed from the first direction D1. The lid member 22 is fixed to the upper end of the peripheral wall portion 21. The lid member 22 closes the first opening 21a. The lid member 22 is disposed above the main body 32. The lid member 22 has a lid body 23 and a heat dissipation portion 25.

The lid body 23 has a plate shape that spreads in a direction orthogonal to the first direction D1. In this embodiment, the lid body 23 is formed of resin. The lid body 23 is provided with a plurality of lid holes 23a. Each lid hole 23a is a hole that penetrates the lid body 23 in the first direction D1. Although not shown in the drawings, each lid hole 23a has a substantially rectangular shape as viewed from the first direction D1.

The heat dissipation portion 25 has a substantially rectangular column shape that protrudes in the first direction D1. In this embodiment, the lid member 22 has a plurality of heat dissipation portions 25. Each heat dissipation portion 25 is disposed inside different lid holes 23a. Each heat dissipation portion 25 is held on the inner surface of the lid hole 23a. In this embodiment, the thermal conductivity of the heat dissipation portion 25 is larger than the thermal conductivity of the lid body 23. The front surface of the heat dissipation portion 25 is exposed to the outside of the lid body 23. That is, a part of the heat dissipation portion 25 is exposed to the outside of the lid body 23. The heat dissipation portion 25 has a first heat dissipation portion 25a, an insulating portion 25f, a second heat dissipation portion 26, and a plurality of holding members 28.

The first heat dissipation portion 25a has a plate shape that spreads in a direction orthogonal to the first direction D1. As viewed from the first direction D1, the first heat dissipation portion 25a has a substantially rectangular shape. The front surface 25b of the first heat dissipation portion 25a is exposed to the outside of the lid body 23. Accordingly, a part of the heat dissipation portion 25 is exposed to the outside of the lid body 23. The first heat dissipation portion 25a is formed of metal such as copper, aluminum, nickel, silver, or gold. In this embodiment, the first heat dissipation portion 25a is formed of copper. The thermal conductivity of the first heat dissipation portion 25 a is larger than the thermal conductivity of the lid body 23.

The insulating portion 25f insulates the first heat dissipation portion 25a from the second heat dissipation portion 26. The insulating portion 25f has a substantially rectangular column shape that protrudes in the first direction D1. The insulating portion 25f is disposed below the first heat dissipation portion 25a. The insulating portion 25f is fixed to a back surface 25c of the first heat dissipation portion 25a. The insulating portion 25f is provided with a recess portion 25i recessed upward from a back surface 25h of the insulating portion. The insulating portion 25f is formed of ceramics such as silicon nitride (Si₃N₄) and aluminum nitride (AlN). In this embodiment, the insulating portion 25f is formed of silicon nitride. The thermal conductivity of the insulating portion 25f is larger than the thermal conductivity of the lid body 23.

The second heat dissipation portion 26 has a substantially rectangular column shape that protrudes in the first direction D1. The second heat dissipation portion 26 is disposed inside the recess portion 25i. The second heat dissipation portion 26 is fixed to the inner surface of the recess portion 25i. The second heat dissipation portion 26 is formed of metal such as copper, aluminum, nickel, silver, or gold. In this embodiment, the second heat dissipation portion 26 is formed of copper. The thermal conductivity of the second heat dissipation portion 26 is larger than the thermal conductivity of the lid body 23. Furthermore, when the insulating portion 25f is not provided with the recess portion 25i, the second heat dissipation portion 26 may be fixed to the back surface 25h of the insulating portion 25f. Further, in this case, the lid member 22 may be formed by insert molding using the heat dissipation portion 25 as an insert member. In this case, the second heat dissipation portion 26 is held by the lid body 23. As shown in FIG. 2, the second heat dissipation portion 26 holds the plurality of holding member 28. The second heat dissipation portion 26 has a housing member 26a and a support member 26e.

The housing member 26a has a substantially rectangular column shape that protrudes in the first direction D1. The housing member 26a is provided with a plurality of housing holes 26c recessed upward from a back surface 26b of the housing member 26a. Each housing hole 26c has a circular shape as viewed from the first direction D1. Each of the plurality of housing holes 26c accommodates a part of one holding member 28 and one elastic member 29. Some housing holes 26c of the plurality of housing holes 26c are arranged at intervals along the second direction D2. Further, although not shown in the drawings, in this embodiment, other housing holes 26c of the plurality of housing holes 26c are arranged at intervals along the third direction D3. Other housing holes 26c may not be arranged at intervals along the third direction D3. In this case, all housing holes 26c are arranged at intervals along the second direction D2.

The support member 26e has a plate shape that spreads in a direction orthogonal to the first direction D1. The support member 26e is fixed to the back surface 26b of the housing member 26a. The support member 26e is provided with a plurality of through-holes 26f that penetrate the support member 26e in the first direction D1. As viewed from the first direction D1, each through-hole 26f has a circular shape. The diameter of the through-hole 26f is smaller than the diameter of the housing hole 26c. As viewed from the first direction D1, each through-hole 26f overlaps with different housing holes 26c. The inside of the housing hole 26c is connected to the inside of the peripheral wall portion 21 via the through-hole 26f.

The holding member 28 has a substantially column shape that extends in the first direction D1. Each holding member 28 holds different heat transfer pins 50 in an attachable and detachable manner. In this embodiment, the holding member 28 is formed of metal such as copper, aluminum, nickel, silver, or gold. In this embodiment, the holding member 28 is formed of copper. The holding member 28 has a first portion 28a, a second portion 28b, and a third portion 28c.

The first portion 28a has a substantially disk shape that extends in a direction orthogonal to the first direction D1. The first portion 28a is accommodated inside the housing hole 26c. The outer diameter of the first portion 28a is larger than the diameter of the through-hole 26f. Accordingly, it is possible to prevent the holding member 28 from being separated from the heat dissipation portion 25. A downward elastic force is applied to the first portion 28a by the elastic member 29.

The second portion 28b has a substantially column shape that protrudes downward from the first portion 28a. The second portion 28b passes through the through-hole 26f. The lower end of the second portion 28b is located below the support member 26e.

The third portion 28c has a substantially column shape that protrudes downward from the second portion 28b. The third portion 28c has a taper shape that decreases in outer diameter as it goes downward. The third portion 28c is provided with a first screw portion 28d. That is, the holding member 28 has the first screw portion 28d. The first screw portion 28d is a male screw provided on the outer peripheral surface of the third portion 28c.

As shown in FIG. 1, the heat dissipation plate 31 has a plate shape that spreads in a direction orthogonal to the first direction D1. The heat dissipation plate 31 is fixed to the lower end of the peripheral wall portion 21. The heat dissipation plate 31 closes the second opening 21b of the peripheral wall portion 21. The heat dissipation plate 31 holds the main body 32. More specifically, the main body 32 is fixed to a front surface 31a of the heat dissipation plate 31. The back surface 31b of the heat dissipation plate 31 is exposed to the outside of the semiconductor device 10. The heat dissipation plate 31 is formed of metal such as copper, aluminum, nickel, silver, or gold. In this embodiment, the holding member 28 is formed of copper. That is, the holding member 28 is formed of metal.

The main body 32 generates, for example, a high-frequency alternating current from a direct current supplied from an external power source (not shown). The main body 32 is accommodated inside the housing 20. The main body 32 is held by the heat dissipation plate 31. In this embodiment, the semiconductor device 10 has a plurality of chips 37. Some chips 37 among the plurality of chips 37 are arranged at intervals in the second direction D2. Although not shown in the drawings, other chips 37 are arranged side by side in the third direction D3. Furthermore, the chips 37 may be arranged at intervals only in the second direction D2. The main body 32 has a substrate 33, a first joint layer 34, a second joint layer 36, a chip 37, a plurality of wires 39, and a sealing portion 60.

A back surface 33f of the substrate 33 is fixed to the front surface 31a of the heat dissipation plate 31 by the first joint layer 34. The first joint layer 34 is formed of a sintered material, for example solder and silver. In this embodiment, the first joint layer 34 is solder. The substrate 33 has a wiring portion 33a, an insulating substrate 33b, and a conductor portion 33c.

The insulating substrate 33b has a plate shape that spreads in a direction orthogonal to the first direction D1. The insulating substrate 33b has insulating properties. The insulating substrate 33b is a ceramic substrate. In this embodiment, the insulating substrate 33b is a ceramic substrate formed of ceramics such as silicon nitride and aluminum nitride.

The wiring portion 33a is provided on the front surface of the insulating substrate 33b. The wiring portion 33a is formed of metal. In this embodiment, the wiring portion 33a is formed of copper. A circuit pattern (not shown) is formed on the wiring portion 33a. The front surface of the wiring portion 33a is a device surface 33e. The device surface 33e is the front surface of the substrate 33. The device surface 33e is a surface among the outer surfaces of the substrate 33 that faces one side (+D1 side) in the first direction D1. The device surface 33e faces the lid member 22 in the first direction D1.

The conductor portion 33c is provided on the back surface of the insulating substrate 33b. The conductor portion 33c is fixed to the front surface 31a of the heat dissipation plate 31 by the first joint layer 34. Accordingly, the main body 32 is held by the heat dissipation plate 31. That is, the heat dissipation plate 31 holds a surface different from the device surface 33e in the outer surface of the substrate 33. The conductor portion 33c is formed of metal. In this embodiment, the conductor portion 33c is formed of copper.

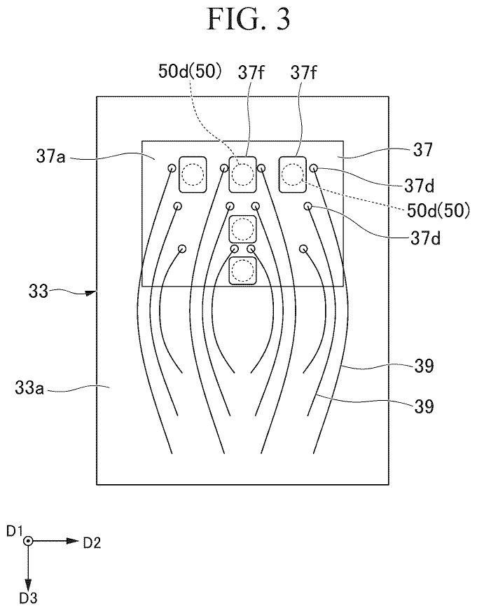

The chip 37 is mounted on the device surface 33e of the substrate 33. More specifically, a back surface 37b of the chip 37 is fixed to the device surface 33e by the second joint layer 36. The second joint layer 36 is formed of a sintered material, for example solder and silver. In this embodiment, the second joint layer 36 is solder. The chip 37 includes, for example, a power element for power control. The chip 37 is formed of a semiconductor material such as silicon (Si), silicon carbide (SiC), or gallium nitride (GaN). Each of the chips 37 of each main body 32 overlaps with the heat dissipation portion 25 of the lid member 22 as viewed from the first direction D1. Therefore, a front surface 37a of the chip 37, which is a surface among the outer surfaces of the chip 37 facing one side (+D1 side) in the first direction D1, faces the heat dissipation portion 25 in the first direction D1. As viewed from the first direction D1, the chip 37 overlaps with the plurality of holding members 28. As shown in FIG. 3, the chip 37 has a substantially rectangular shape as viewed from the first direction D1. The chip 37 is provided with a plurality of electrode portions 37d and a protective portion 37f.

Each of the plurality of electrode portions 37d is provided on the front surface 37a of the chip 37. Each electrode portion 37d is formed of metal. In this embodiment, each electrode portion 37d is formed of aluminum. The protective portion 37f is provided on the front surface 37a of the chip 37. That is, the protective portion 37f is provided on the outer surface of the chip 37. The chip 37 is provided with the plurality of protective portions 37f. Each protective portion 37f is formed of, for example, resin such as polyimide (PI) or acrylic resin, or a metal such as copper. In this embodiment, each protective portion 37f is formed of polyimide. Each protective portion 37f is disposed at a position not overlapping with the electrode portion 37d as viewed from the first direction D1. Furthermore, when each protective portion 37f is made of a conductive material such as copper, a part of each protective portion 37f may be disposed to overlap with the electrode portion 37d.

As shown in FIG. 1, each of the plurality of wires 39 electrically connects the chip 37 and the wiring portion 33a. The wire 39 is formed of, for example, metal such as aluminum and copper. In this embodiment, the wire 39 is formed of aluminum. As shown in FIG. 3, one end of each wire 39 is joined to different electrode portions 37d of the chip 37. The other end of each wire 39 is joined to the wiring portion 33a. As a result, each of the plurality of wires 39 connects different electrode portions 37d and the substrate 33.

As shown in FIG. 1, the sealing portion 60 covers the main body 32. The sealing portion 60 covers the chip 37. A part of the sealing portion 60 is disposed between the chip 37 and the lid member 22. The sealing portion 60 is formed of insulating resin. The sealing portion 60 is formed of resin that mainly contains, for example, epoxy resin, phenolic resin, or acrylic resin. In this embodiment, the sealing portion 60 is formed of silicone resin. In this embodiment, the sealing portion 60 is in a gel state. The sealing portion 60 can ensure the insulating properties between the electrode portions 37d, between the wires 39, and between the electrode portions 37d and the wires 39. Further, the sealing portion 60 can protect the main body 32. Thus, according to this embodiment, the sealing portion 60 can improve the stability of the operation of the semiconductor device 10.

The heat transfer pin 50 has a bar shape that extends in the first direction D1. In this embodiment, the heat transfer pin 50 has a substantially column shape that extends in the first direction D1. The heat transfer pin 50 may have other shapes, such as a rectangular column shape. As shown in FIG. 2, the heat transfer pin 50 has a taper shape that decreases in outer diameter as it goes downward. The outer diameter of the lower end of the heat transfer pin 50, that is, the end on the other side (−D1 side) in the first direction D1, is smaller than the outer diameter of the upper end, that is, the end on one side (+D1 side) in the first direction D1. The outer diameter of the lower end of the heat transfer pin 50 is preferably 50 μm or more and 1.0 mm or less. The heat transfer pin 50 is formed of metal such as copper, aluminum, silver, or gold. In this embodiment, the heat transfer pin 50 is formed of copper. That is, the heat transfer pin 50 is formed of metal. The thermal conductivity of the heat transfer pin 50 is preferably larger than 200 [W/m·K].

As shown in FIG. 1, in this embodiment, the lower end of the heat transfer pin 50 contacts the front surface 37a of the chip 37. The semiconductor device 10 has the plurality of heat transfer pins 50. It is preferable that each of the plurality of heat transfer pins 50 is disposed so that one or more heat transfer pins 50 contact one chip 37. As shown in FIG. 2, the heat transfer pin 50 has a second screw portion 50a.

The second screw portion 50a is a female screw that is recessed downward from the upward facing surface of the heat transfer pin 50. The second screw portion 50a is screw-fitted to the first screw portion 28d of the holding member 28. Accordingly, the holding member 28 holds heat transfer pin 50 in an attachable and detachable manner. Further, the heat transfer pin 50 is held by the heat dissipation portion 25 via the holding member 28. The heat transfer pin 50 extends downward from the holding member 28. As described above, each chip 37 overlaps with the holding member 28 as viewed from the first direction D1. Therefore, as shown in FIG. 1, the heat transfer pin 50 extends from the lid member 22 toward the chip 37. Furthermore, as shown in FIG. 2, the heat transfer pins 50 do not need to be attached to all holding members 28, and the heat transfer pins 50 may not be attached to some holding members 28. That is, in this embodiment, the holding member 28 having the heat transfer pin 50 attached thereto can be selected.

According to this embodiment, the holding member 28 has the first screw portion 28d, and the heat transfer pin 50 has the second screw portion 50a screw-fitted to the first screw portion 28d. Therefore, in the process of manufacturing the semiconductor device 10, the heat transfer pin 50 can be easily attached to the holding member 28. Thus, an increase in the number of steps in manufacturing the semiconductor device 10 can be suppressed.

As shown in FIG. 1, the heat transfer pin 50 is inserted into the sealing portion 60. As described above, a lower end 50d of the heat transfer pin 50 contacts the front surface 37a of the chip 37. More specifically, as shown in FIG. 3, the lower end 50d of each heat transfer pin 50 contacts the protective portion 37f provided on the front surface 37a of the chip 37. Therefore, according to this embodiment, since the heat transfer pin 50 contacts the chip 37 via the protective portion 37f, it is possible to suppress the heat transfer pin 50 from directly contacting the chip 37. Therefore, it is possible to suppress the chip 37 from being damaged due to direct contact with the heat transfer pin 50. Therefore, it is possible to improve the stability of the operation of the semiconductor device 10.

According to this embodiment, the lid member 22 has the plurality of holding members 28 that hold different heat transfer pins 50 in an attachable and detachable manner. Therefore, the holding member 28 having the heat transfer pin 50 attached thereto as described above can be selected. For that reason, the heat transfer pin 50 can be attached only to the holding member 28 that is disposed not to overlap with the plurality of electrode portions 37d and the plurality of wires 39 of the chip 37 as viewed from the first direction D1. Accordingly, it is possible to suppress the heat transfer pin 50 from contacting the electrode portion 37d and the wire 39 during the process of manufacturing the semiconductor device 10 and the operation of the semiconductor device 10. Therefore, it is possible to suppress the electrode portion 37d and the wire 39 from being damaged and to suppress the wire 39 from being separated from the electrode portion 37d. Therefore, the stability of the operation of the semiconductor device 10 can be improved more suitably.

Further, in this embodiment, it is possible to select the holding member 28 having the heat transfer pin 50 attached thereto by the arrangement of the electrode portion 37d provided in the chip 37 and the wiring of the wire 39. Therefore, it is easy to use the lid member 22 of the same configuration even when the semiconductor device 10 includes the main body 32 in which the electrode portion 37d has a different arrangement and the wire 39 has a different wiring. Therefore, since the versatility of the lid member 22 can be improved, an increase in the number of manufacturing steps and manufacturing costs of the lid member 22 can be suppressed.

Although not shown in the drawings, in the step of fixing the lid member 22 to the peripheral wall portion 21 in the process of manufacturing the semiconductor device 10, the lid member 22 holding the heat transfer pin 50 is moved downward from the upper side of the main body 32 covered by the sealing portion 60. As described above, in this embodiment, the heat transfer pin 50 is formed of metal. Further, as described above, in this embodiment, the sealing portion 60 is formed of gel resin. The hardness of the heat transfer pin 50 is higher than the hardness of the sealing portion 60. Therefore, the heat transfer pin 50 can be easily inserted into the sealing portion 60 in accordance with only the operation of moving the lid member 22 holding the heat transfer pin 50 downward in the step of fixing the lid member 22 to the peripheral wall portion 21. Therefore, the lower end of the heat transfer pin 50 can be easily disposed near the chip 37 in accordance with only the operation of moving the lid member 22 downward from above. More specifically, in this embodiment, the lower end of the heat transfer pin 50 can be easily brought into contact with the chip 37 in accordance with only the operation of moving the lid member 22 downward from above. Therefore, an increase in the number of steps in manufacturing the semiconductor device 10 can be suppressed.

As shown in FIG. 2, the elastic member 29 is disposed inside the housing hole 26c of the heat dissipation portion 25. The elastic member 29 is disposed above the holding member 28. The upper end of the elastic member 29 is supported by a downward facing surface among the inner surfaces of the housing hole 26c. The lower end of the elastic member 29 is supported by the first portion 28a of the holding member 28. The elastic member 29 applies a downward elastic force to the holding member 28. The elastic member 29 applies an elastic force toward the chip 37 to the heat transfer pin 50 via the holding member 28. Furthermore, in this embodiment, the elastic member 29 is a coil spring. The elastic member 29 may be a spring of another configuration, such as a leaf spring.

According to this embodiment, the semiconductor device 10 includes the main body 32 which has the substrate 33 and the chip 37 which is mounted on the device surface 33e facing the upper side, that is, one side (+D1 side) in the first direction D1 among the outer surfaces of the substrate 33, the housing 20 which accommodates the main body 32, and the heat transfer pin 50, the housing 20 has the lid member 22 that faces the device surface 33e, and the heat transfer pin 50 is held by the lid member 22 and extends from the lid member 22 toward the chip 37. Therefore, as shown in FIG. 1, since the lower end of the heat transfer pin 50 can be disposed near the chip 37, heat generated in the chip 37 can be transferred to the lid member 22 via the heat transfer pin 50. Further, the heat of the chip 37 transferred to the lid member 22 can be dissipated to the outside of the semiconductor device 10. Accordingly, since it is possible to suppress the temperature of the chip 37 from becoming excessively high, it is possible to improve the stability of the operation of the semiconductor device 10.

According to this embodiment, the heat transfer pin 50 is formed of metal and contacts the chip 37. Therefore, it is possible to increase the thermal conductivity of the heat transfer pin 50 compared to a case in which the heat transfer pin 50 is formed of resin. Further, since the heat transfer pin 50 contacts the chip 37, it is possible to increase the amount of heat transferred from the chip 37 to the heat transfer pin 50. Accordingly, it is possible to more favorably increase the amount of heat transferred from the chip 37 to the lid member 22 via the heat transfer pin 50. Therefore, since it is possible to more favorably suppress the temperature of the chip 37 from becoming excessively high, it is possible to more favorably improve the stability of the operation of the semiconductor device 10.

According to this embodiment, the lid member 22 has the lid body 23 and the heat dissipation portion 25, the heat transfer pin 50 is held by the heat dissipation portion 25, the thermal conductivity of the heat dissipation portion 25 is higher than the thermal conductivity of the lid body 23, and a part of the heat dissipation portion 25 is exposed to the outside of the lid body 23. Therefore, it is possible to increase the amount of heat transferred from the chip 37 to the lid member 22 via the heat transfer pin 50 compared to a case in which the heat transfer pin 50 is held by the lid body 23. Further, since a part of the heat dissipation portion 25 is exposed to the outside of the lid body 23, it is possible to increase the amount of heat dissipated from the lid member 22 to the outside of the semiconductor device 10. Accordingly, it is possible to increase the amount of heat dissipated from the chip 37 to the outside of the semiconductor device 10 via the heat transfer pin 50 and the heat dissipation portion 25. Therefore, since it is possible to more favorably suppress the temperature of the chip 37 from becoming excessively high, it is possible to more favorably improve the stability of the operation of the semiconductor device 10.

According to this embodiment, the semiconductor device 10 includes the elastic member 29 that applies an elastic force toward the chip 37 to the heat transfer pin 50. Therefore, even if the dimensional tolerances in the first direction D1 of the members constituting the housing 20 and the members constituting the main body 32 are large, the heat transfer pins 50 can be brought into stable contact with the chips 37. Accordingly, since it is possible to suppress an increase in thermal resistance between the heat transfer pin 50 and the chip 37, it is possible to suppress a decrease in amount of heat transferred from the chip 37 to the heat transfer pin 50. Therefore, it is possible to suppress a decrease in amount of heat transferred to the lid member 22 via the heat transfer pin 50. Therefore, even if the dimensional tolerances in the first direction D1 of the members constituting the housing 20 and the members constituting the main body 32 are large, it is possible to suppress the temperature of the chip 37 from becoming excessively high. Therefore, it is possible to more favorably improve the stability of the operation of the semiconductor device 10.

Since the substrate 33 is thermally deformed due to the heat generated in the chip 37 and the wiring portion 33a during the operation of the semiconductor device 10, the position of the chip 37 may change in the first direction D1. On the other hand, as described above, the semiconductor device 10 of this embodiment includes the elastic member 29 that applies an elastic force toward the chip 37 to the heat transfer pin 50. Therefore, the heat transfer pin 50 can be brought into stable contact with the chip 37 even when the position of the chip 37 in the first direction D1 changes due to the thermal deformation of the substrate 33. Accordingly, as described above, since it is possible to suppress a decrease in amount of heat transferred from the chip 37 to the heat transfer pin 50, it is possible to suppress the temperature of the chip 37 from becoming excessively high. Therefore, it is possible to more favorably improve the stability of the operation of the semiconductor device 10.

According to this embodiment, the outer diameter of the lower end of the heat transfer pin 50 is smaller than the outer diameter of the upper end thereof. Thus, since it is possible to decrease the outer diameter of the lower end of the heat transfer pin 50 contacting the chip 37, it is possible to more favorably suppress the heat transfer pin 50 from contacting the electrode portion 37d and the wire 39 as shown in FIG. 3. Accordingly, it is possible to more favorably suppress the electrode portion 37d and the wire 39 from being damaged and to more favorably suppress the wire 39 from being separated from the electrode portion 37d. Therefore, it is possible to more favorably improve the stability of the operation of the semiconductor device 10.

Further, according to this embodiment, since it is possible to increase the outer diameter of the upper portion of the heat transfer pin 50, it is easy to decrease the thermal resistance of the heat transfer pin 50. Therefore, it is possible to more favorably increase the amount of heat transferred from the chip 37 to the lid member 22 via the heat transfer pin 50. Therefore, since it is possible to more favorably suppress the temperature of the chip 37 from becoming excessively high, it is possible to more favorably improve the stability of the operation of the semiconductor device 10.

According to this embodiment, the semiconductor device 10 includes the metallic heat dissipation plate 31 which holds a surface different from the device surface 33e in the outer surface of the substrate 33. Therefore, it is possible to dissipate heat generated in the chip 37 to the outside of the semiconductor device 10 via the heat dissipation plate 31. Accordingly, it is possible to further increase the amount of heat dissipated from the chip 37 to the outside of the semiconductor device 10. Therefore, since it is possible to more favorably suppress the temperature of the chip 37 from becoming excessively high, it is possible to more favorably improve the stability of the operation of the semiconductor device 10.

### Second Embodiment

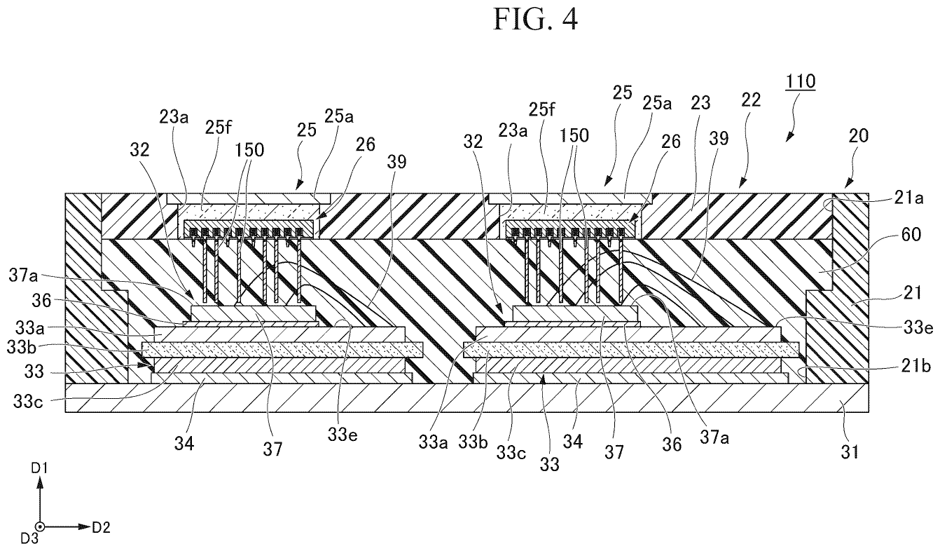

FIG. 4 is a schematic cross-sectional view showing a semiconductor device 110 of this embodiment. In the semiconductor device 110 of this embodiment, a heat transfer pin 150 does not contact the chip 37. Furthermore, in the following description, the same components as those in the first embodiment described above are denoted by the same reference numerals, and the description thereof will be omitted.

The heat transfer pin 150 has a substantially column shape that extends in the first direction D1. The heat transfer pin 150 is inserted into the sealing portion 60. As described above, in this embodiment, the heat transfer pin 150 does not contact the chip 37. More specifically, the lower end of the heat transfer pin 150 is located in the vicinity of the chip 37. The sealing portion 60 is disposed between the lower end of the heat transfer pin 150 and the chip 37. That is, the heat transfer pin 150 contacts the chip 37 via the sealing portion 60. The other configurations of the heat transfer pin 150 of this embodiment are the same as the other configurations of the heat transfer pin 50 of the first embodiment described above.

According to this embodiment, the heat transfer pin 150 is held by the lid member 22, extends from the lid member 22 toward the chip 37, and is inserted into the sealing portion 60. When the sealing portion 60 is not provided, heat generated in the chip 37 is transferred to the heat transfer pin 150 via air. Therefore, the amount of heat transferred from the chip 37 to the heat transfer pin 150 is small. On the other hand, in this embodiment, the chip 37 and the heat transfer pin 150 are in contact with each other via the sealing portion 60 having thermal conductivity higher than that of air. Therefore, it is possible to increase the amount of heat transferred from the chip 37 to the heat transfer pin 150 compared to a case in which the sealing portion 60 is not provided. Therefore, since it is possible to suppress the temperature of the chip 37 from becoming excessively high, it is possible to improve the stability of the operation of the semiconductor device 110.

### Third Embodiment

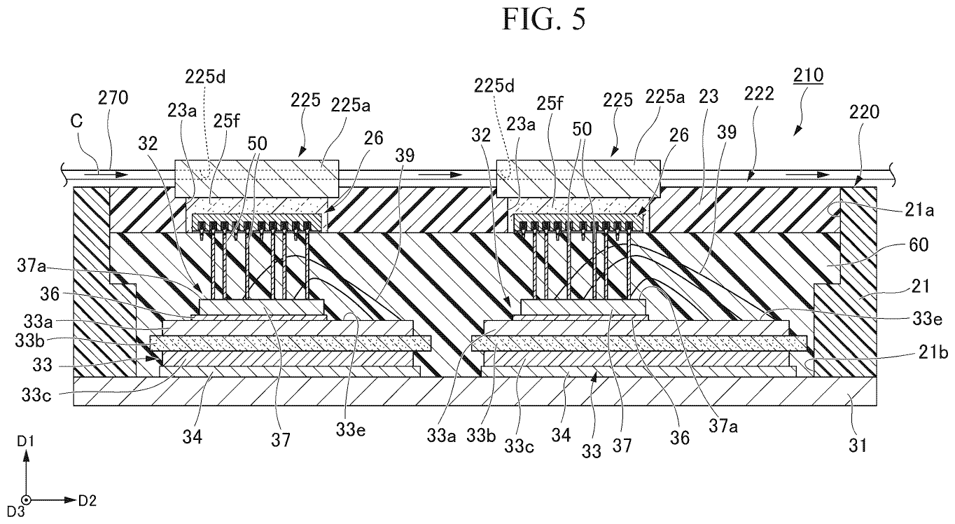

FIG. 5 is a schematic cross-sectional view showing a semiconductor device 210 of this embodiment. The semiconductor device 210 of this embodiment includes a refrigerant flow path 270. Furthermore, in the following description, the same components as those in the first embodiment described above are denoted by the same reference numerals, and the description thereof will be omitted.

A lid member 222 of a housing 220 of this embodiment has a plate shape that spreads in a direction orthogonal to the first direction D1. The lid member 222 is disposed above the main body 32. The lid member 222 has the lid body 23 and a heat dissipation portion 225.

The heat dissipation portion 225 has a substantially rectangular column shape that protrudes in the first direction D1. The heat dissipation portion 225 is held by the inner surface of the lid hole 23a. The heat dissipation portion 225 has a first heat dissipation portion 225a, an insulating portion 25f, a second heat dissipation portion 26, and a plurality of holding members 28.

The first heat dissipation portion 225a has a substantially rectangular column shape that protrudes in the first direction D1. The lower portion of the first heat dissipation portion 225a is located inside the lid hole 23a. The upper portion of the first heat dissipation portion 225a is located above the lid body 23. The upper portion of the first heat dissipation portion 225a is exposed from the lid body 23. An insertion portion 225d is provided in a portion of the first heat dissipation portion 225 above the lid body 23. The insertion portion 225d is a hole through which the first heat dissipation portion 225a penetrates in the second direction D2. In this embodiment, the insertion portion 225d has a circular shape as viewed from the second direction D2. The insertion portion 225d may be a hole of other shapes such as a square shape and an elliptical shape. The other configurations of the first heat dissipation portion 225a are the same as the other configurations of the first heat dissipation portion 25a of the first embodiment described above.

The refrigerant flow path 270 is a pipe through which a refrigerant C flows. A part of the refrigerant flow path 270 passes through the insertion portion 225d. Therefore, a part of the refrigerant flow path 270 is provided in the heat dissipation portion 225. As viewed from the second direction D2, the refrigerant flow path 270 has an annular shape. A portion through which the insertion portion 225d passes in the refrigerant flow path 270 is held by the inner peripheral surface of the insertion portion 225d. A portion through which the insertion portion 225d passes in the refrigerant flow path 270 contacts the inner peripheral surface of the insertion portion 225d. The refrigerant flow path 270 is formed of metal such as copper or aluminum. In this embodiment, the refrigerant flow path 270 is formed of copper. In this embodiment, the refrigerant C is water. The refrigerant C may be other liquid refrigerants such as methanol and ethanol, or gaseous refrigerants such as methane and ethane.

According to this embodiment, the semiconductor device 210 includes the refrigerant flow path 270 through which the refrigerant C flows, and a part of the refrigerant flow path 270 is provided in the heat dissipation portion 225. Therefore, the heat of the chip 37 transferred to the heat dissipation portion 225 via the heat transfer pin 50 can be transferred to the refrigerant C flowing through the refrigerant flow path 270. Therefore, the heat of the chip 37 transferred to the heat dissipation portion 225 can be dissipated from the heat dissipation portion 225 to the air outside the semiconductor device 210 and can be dissipated to the outside of the semiconductor device 210 by the refrigerant C. Therefore, it is possible to increase the amount of heat dissipated from the heat dissipation portion 225 to the outside of the semiconductor device 210. Therefore, since it is possible to more favorably suppress the temperature of the chip 37 from becoming excessively high, it is possible to more favorably improve the stability of the operation of the semiconductor device 210.

### Fourth Embodiment

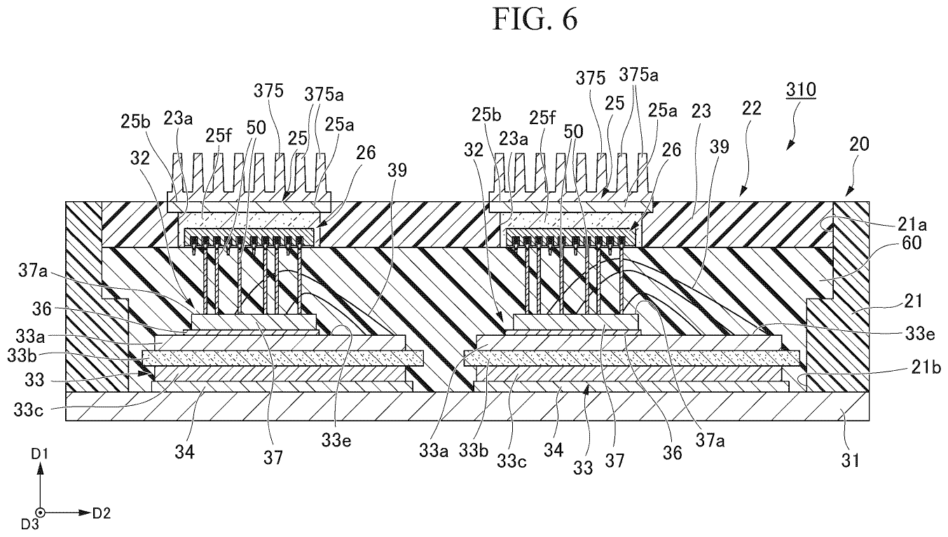

FIG. 6 is a schematic cross-sectional view showing a semiconductor device 310 of this embodiment. The semiconductor device 310 of this embodiment includes a heat dissipation member 375. Furthermore, in the following description, the same components as those in the first embodiment described above are denoted by the same reference numerals, and the description thereof will be omitted.

In this embodiment, the heat dissipation member 375 is a heat sink. The heat dissipation member 375 is formed of metal such as copper or aluminum. In this embodiment, the heat dissipation member 375 is formed of copper. The heat dissipation member 375 has a plurality of fins 375a protruding upward. The heat dissipation member 375 is disposed outside the housing 20. The heat dissipation member 375 is attached to the front surface 25b of the first heat dissipation portion 25a. That is, the heat dissipation member 375 is attached to the outer surface of the heat dissipation portion 25. The heat dissipation member 375 dissipates heat of the lid member 22 to the outside of the housing 20. As described above, since the heat dissipation member 375 has the plurality of fins 375a, it is possible to increase the contact area between the heat dissipation member 375 and the air outside the semiconductor device 310.

According to this embodiment, the semiconductor device 310 includes the heat dissipation member 375 that is attached to the outer surface of the heat dissipation portion 25 and dissipates heat of the lid member 22 to the outside of the housing 20. Therefore, it is possible to dissipate the heat, generated in the chip 37 and transferred to the heat dissipation portion 25 via the heat transfer pin 50, to the outside of the semiconductor device 310 via the heat dissipation member 375. As described above, since the contact area between the heat dissipation member 375 and the air outside the semiconductor device 310 is wide, it is possible to increase the amount of heat dissipated from the heat dissipation member 375 to the outside of the semiconductor device 310. Therefore, since it is possible to more favorably suppress the temperature of the chip 37 from becoming excessively high, it is possible to more favorably improve the stability of the operation of the semiconductor device 310.

According to at least one embodiment described above, it is possible to provide the semiconductor device which can be operated stably by including the lid member facing the device surface and the heat transfer pin held by the lid member and extending from the lid member toward the chip.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a main body which has a substrate and a chip mounted on a device surface facing one side in a first direction among outer surfaces of the substrate;
a housing which accommodates the main body; and
a heat transfer pin,
wherein the housing has a lid member that faces the device surface, and
the heat transfer pin is held by the lid member and extends from the lid member toward the chip.

2. The semiconductor device according to claim 1,
wherein the heat transfer pin is formed of metal and contacts the chip.

3. The semiconductor device according to claim 2,
wherein a protective portion is provided in an outer surface of the chip, and
the heat transfer pin contacts the protective portion.

4. The semiconductor device according to claim 1,
wherein the main body has a sealing portion that covers the chip,
the sealing portion has insulating properties, and
the heat transfer pin is inserted into the sealing portion.

5. The semiconductor device according to claim 1,
wherein the lid member has a lid body and a heat dissipation portion,
the heat transfer pin is held by the heat dissipation portion,
the thermal conductivity of the heat dissipation portion is higher than the thermal conductivity of the lid body, and
a part of the heat dissipation portion is exposed to the outside of the lid body.

6. The semiconductor device according to claim 5, further comprising:
a refrigerant flow path through which a refrigerant flows,
wherein a part of the refrigerant flow path is provided in the heat dissipation portion.

7. The semiconductor device according to claim 5, further comprising:
a heat dissipation member that is attached to an outer surface of the heat dissipation portion and dissipates heat of the lid member to the outside of the housing.

8. The semiconductor device according to claim 1,
wherein the lid member has a plurality of holding members that hold the heat transfer pin in an attachable and detachable manner.

9. The semiconductor device according to claim 8,
wherein the holding member has a first screw portion, and
the heat transfer pin has a second screw portion which is screw-fitted to the first screw portion.

10. The semiconductor device according to claim 1, further comprising:
an elastic member that applies an elastic force toward the chip to the heat transfer pin.

11. The semiconductor device according to claim 1,
wherein an outer diameter of an end of the heat transfer pin on the other side in the first direction is smaller than an outer diameter of an end thereof on one side in the first direction.

12. The semiconductor device according to claim 1, further comprising:
a metallic heat dissipation plate which holds a surface different from the device surface among outer surfaces of the substrate.

13. The semiconductor device according to claim 1,
wherein the main body has a plurality of wires,
a plurality of electrode portions are provided in a surface that faces one side in the first direction among outer surfaces of the chip, and
each of the plurality of wires connects the different electrode portions and the substrate.
